(19) United States
(12) Patent Application Publication
(10) Pub. No.: US 2003/0003676 A1
(43) Pub. Date: Jan. 2, 2003

(54) Ultra-fine alignment system and method using acoustic-AFM interaction

(76) Inventors: Brian Lee, New York, NY (US); Gary Williams, Fishkill, NY (US); Zhijian Lu, Poughkeepsie, NY (US); Graham Ballantyne, Northumberland (GB)

Correspondence Address: Infineon Technologies North America Corp., c/o Siemens Corporation, Intellectual Property Department, 186 Wood Avenue South, Iselin, NJ, 08830, US

(21) Appl. No.: 09/892,805

(22) Filed: Jun. 27, 2001

(51) Int. Cl. H01L 21/76

(52) U.S. Cl. 438/401

(57) ABSTRACT

Systems and methods for deciphering an alignment feature are disclosed. A feature is provided on a semiconductor wafer having an elasticity that is different from material surrounding the feature. A stress is applied to the wafer, the feature is scanned with an atomic force microscope to determine a position of the feature. The position of the feature is based on an elasticity difference detected between the feature and the material surrounding the feature.

### BACKGROUND

1. Technical Field

This disclosure relates to semiconductor fabrication, and more particularly, to a system and method for aligning lithographic patterns by employing acoustic energy and atomic force microscopy (AFM).

2. Description of the Related Art

Semiconductor devices are processed in levels. Materials are formed in layers and patterned, typically using lithographic processes. To build devices and components on semiconductor devices, layers of materials are employed. These layers must be properly aligned so that patterns and components on different layers line up and function correctly once fabricated. Lithographic alignment on prior levels is critical to ensure proper overlay. Lithographic alignment typically includes providing a bullet and target arrangement where the bullet is an alignment mark to be aligned against a target alignment mark.

These alignment marks may include features with sharp edges, for example, trenches or plateaus formed on a layer of the semiconductor device. A photomask includes alignment features corresponding to the features (e.g., alignment marks) formed in a previous level of the semiconductor device. The features of the photomask are aligned to the features of the semiconductor device to ensure proper overlay.

Alignment of these marks is typically performed by an optical system. Either bright field or dark field broad band illumination is used to detect the prior level alignment marks (e.g., the alignment marks formed on the device). Broad band illumination is employed to make a plurality of wavelengths of light available to detect the prior level alignment marks. Light is incident on a surface and is reflected back in different areas based on the thickness of different features. For example, if light is directed normal to a surface having a plateau formed thereon, light would be reflected from a top surface of the plateau and from surfaces adjacent to the base of the plateau. The reflected light from both surfaces includes the same wavelengths, but are out of phase by the thickness of the plateau. This causes an interference condition, either constructive or destructive depending on the thickness and the wavelength of light employed. Since a broad band spectrum is employed many wavelengths are available to perform this measurement and improve contrast of the feature or alignment mark, in this case, a plateau.

Although broad band illumination is used to enhance the contrast of the alignment marks, there are still instances, where the properties of the stack on the alignment marks and of the surrounding area have very low contrast. For example, small thickness variations can cause the complete loss of contrast. For dark field illumination, the angle of light incidence or detection can lead to image misplacement.

Therefore, a need exists for a system and method for improving the contrast of alignment features to provide greater accuracy in deciphering the alignment features.

### SUMMARY OF THE INVENTION

Systems and methods for deciphering an alignment feature are disclosed. A feature is provided on a semiconductor wafer having an elasticity that is different from material surrounding the feature. A stress is applied to the wafer, the feature is scanned with an atomic force microscope to determine a position of the feature. The position of the feature is based on an elasticity difference detected between the feature and the material surrounding the feature.

A system for aligning a pattern to a semiconductor wafer includes a feature formed on the wafer, and the feature includes an elasticity that is different from material surrounding the feature. An acoustic source directs an acoustic beam on the surface of the wafer to apply stress to the wafer. An atomic force microscope includes a tip. The tip scans the feature to determine a position of the feature based on an elasticity difference detected between the feature and the material surrounding the feature.

A system for aligning a pattern to a semiconductor wafer, includes a feature formed on the wafer, and the feature includes an elasticity that is different from material surrounding the feature. An atomic force microscope has a cantilevered tip. An acoustic transmitter is coupled to the cantilevered tip to apply acoustical energy to the wafer by vibrating the cantilever tip such that the cantilevered tip scans the feature to determine a position of the feature based on the elasticity difference between the feature and the material surrounding the feature.

These and other objects, features and advantages of the present invention will become apparent from the following detailed description of illustrative embodiments thereof, which is to be read in connection with the accompanying drawings.

### BRIEF DESCRIPTION OF DRAWINGS

This disclosure will present in detail the following description of preferred embodiments with reference to the following figures wherein:

FIG. 1 is a cross-sectional view of a semiconductor wafer having illustrative alignment features formed in accordance with the present invention;

FIG. 2 is a partial cross-sectional view of a semiconductor wafer showing an atomic source microscope using acoustic energy to decipher an alignment feature in accordance with the present invention;

FIG. 3 is a partial cross-sectional view of a semiconductor wafer showing an atomic source microscope with a cantilevered tip using acoustic energy to decipher an alignment feature in accordance with the present invention;

FIG. 4 is a flow diagram showing an illustrative method for semiconductor alignment in accordance with the present invention; and

FIG. 5 is a block diagram showing an illustrative system for semiconductor alignment in accordance with the present invention.

### DETAILED DESCRIPTION OF PREFERRED EMBODIMENTS

The present invention provides new systems and methods for deciphering alignment mark positions. The present invention employs alignment marks formed from a different material than the substrate or layer in which the mark is formed. By focusing an acoustic beam or by other methods of applying acoustic energy to the substrate of layer, an atomic force microscope (AFM) is employed to detect edges of the alignment marks. The present invention significantly increases alignment mark detection accuracy over prior art light illumination/interference techniques.

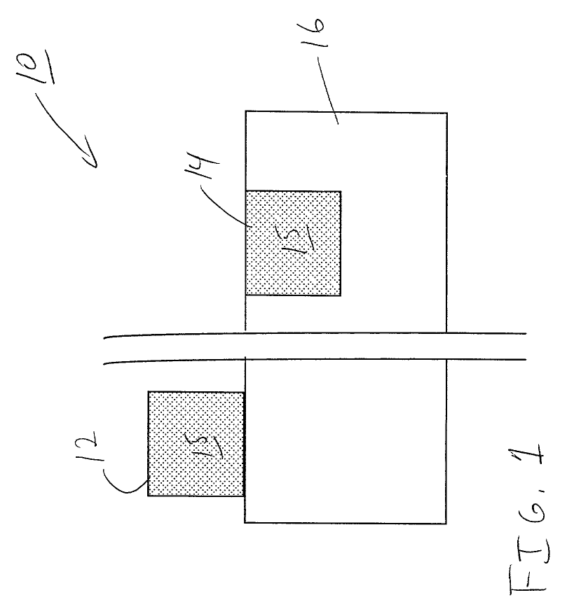

Referring now in specific detail to the drawings in which like reference numerals identify similar or identical elements throughout the several views, and initially to FIG. 1, an alignment mark pattern 10 is shown in accordance with the present invention. Alignment marks 12 and 14 may include plateaus or trenches, respectively. Marks 12 or 14 include a target pattern while marks on a mask or tool (not shown) may include a bullet pattern to be aligned against the target pattern. In accordance with the present invention marks 12 or 14 are formed from a material, which has a different acoustic response from the layer or substrate 16 marks 12 or 14 are formed on (or formed in).

In one embodiment, a layer 16 includes a substrate of a semiconductor wafer. Marks 14 are formed by etching trenches in substrate 16 and filling trenches with a material 15, which has a different acoustic response from substrate 16. Alternately, marks 12 are formed by depositing the material on layer 16 and patterning the materials to form marks 12.

Marks 12 may include any material, which has at least one distinguishable acoustic property as compared to layer 16. In one example, the materials of marks 12 or 14 have a different elasticity (for example, modulus of elasticity, E) as compared to layer 16. The material of marks 12 or 14 may include a resist material (e.g., organic resists), polysilicon, amorphous silicon, silicate glasses (e.g., BPSG), SOG, SiN, ARC or any other suitable materials, which have a different elastic constant and thus have a different acoustic response from, e.g., a Si substrate.

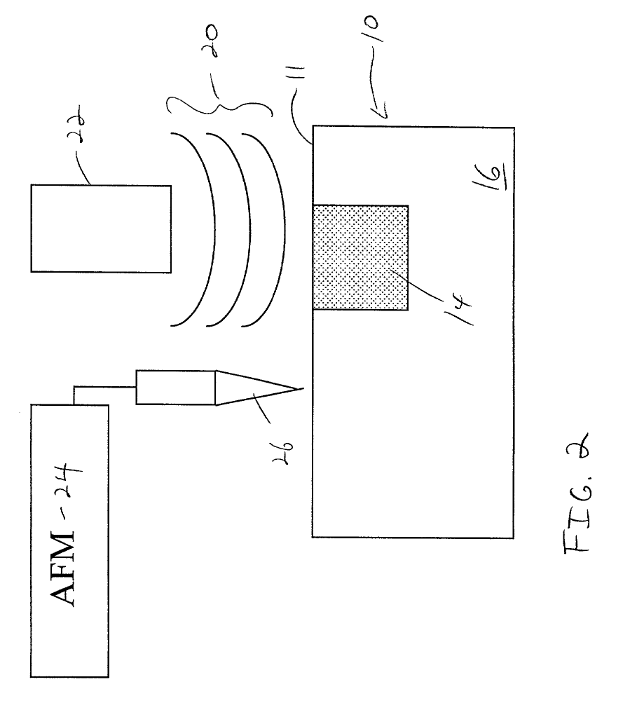

Referring to FIG. 2, a cross-sectional view of a semiconductor wafer 10 is shown. Acoustic energy 20 is applied a surface 11 of wafer 10 from an acoustic energy source 22, such as, for example, an ultrasonic oscillator. Acoustic energy source 22 may include a customized ultrasound gun or any standard acoustic source adapted to focus acoustic energy on wafer 10. Acoustic energy 20 causes vibrations to propagate through wafer 10 and alignment mark 14, causing stress/strain in the materials thereof.

An atomic force microscope (AFM) 24 is employed to detect the differences in the stress/strain fields created by the acoustic energy 20. AFM 24 includes a tip 26, which is moved over wafer 10 and alignment mark 14 to determine with atomic scale resolution where the interface between alignment mark 14 and wafer 10 occurs. By introducing alignment mark 14 into wafer 10 processing, where the mark 14 material has a different elastic constant than the surrounding substrate or layer 16, special resolution can be achieved in accordance with the present invention.

In one embodiment, a focused acoustic beam 20 is placed just above the wafer surface, with an ultra fine AFM tip 26 in close proximity, then an image of alignment mark 14 is formed. The focused acoustic beam operating at ultrasonic frequencies will penetrate into the wafer surface and the AFM tip can be used to detect the response of surface 11. Because ultrasound propagates as a function of the material, the change in elastic properties between mark 14 and substrate 16 will result in a detectable difference at AFM tip 26.

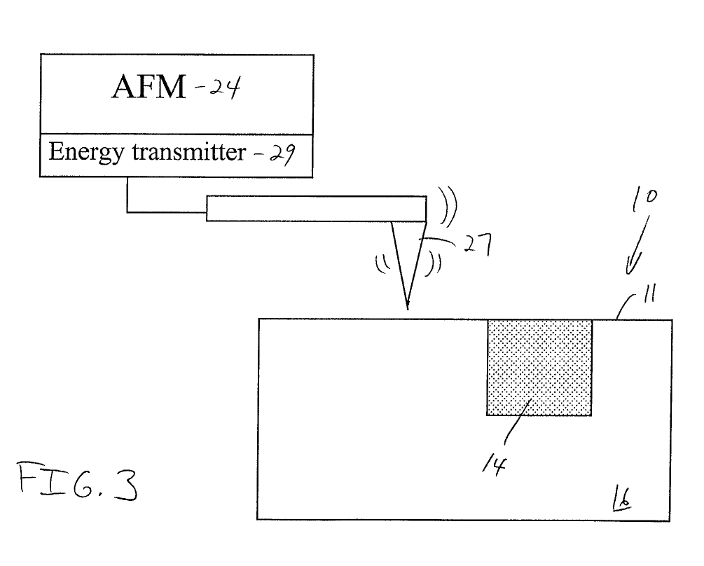

The focused acoustic beam 22 has a resolution equivalent to the wavelength of the acoustic waves propagated. This may be of order of about 1 micron. However, if tip 24 includes an AFM cantilever tip 27 as a transmitter of acoustical oscillations as shown in FIG. 3, then the resolution is merely limited to the AFM tip radius, currently between about 10 and about 20 nm. In FIG. 3, cantilever tip 27 transfers acoustic energy to surface 11 by vibrating. The vibrations are propagated through tip by acoustic transmitter or oscillator 29 of AFM 24.

Alignment systems currently use optical methods for resolving alignment marks with much poorer actual resolution than an AFM. However, the current systems use complex signal analysis and multiple mark arrays to achieve greater resolution and mark positioning accuracy.

By employing similar methods of an array of ‘stress’ marks plus signal analysis and edge detection, the Acoustic-AFM approach can achieve even greater accuracy.

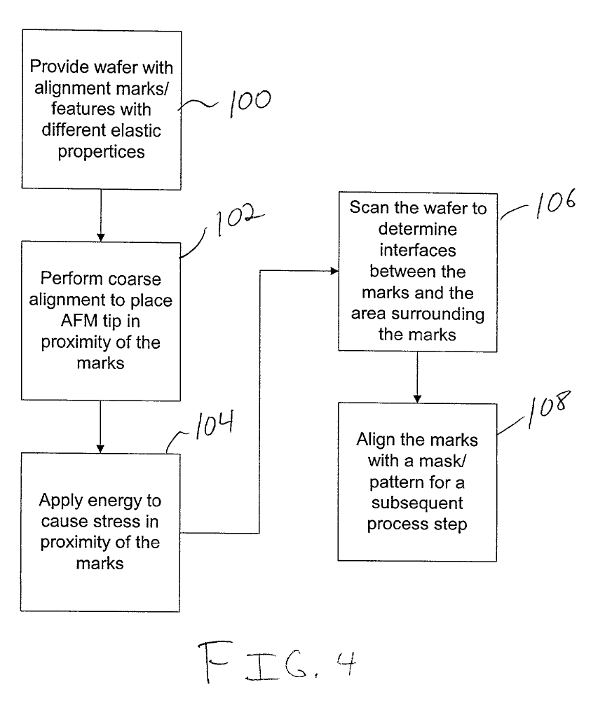

Referring to FIG. 4, a flow chart is shown for an alignment mark detection and alignment method in accordance with an illustrative embodiment of the present invention. In block 100, a semiconductor wafer is provided with alignment marks formed on or in a substrate or layer of the wafer. The alignment marks include a material with different acoustic response properties than the wafer or layer on which the alignment marks are formed. In a preferred embodiment, the alignment marks include a material with different elastic properties as compared to the areas surrounding the alignment marks.

In an alternate embodiment, any feature or structure may be employed as an alignment mark. For example, functional components of the semiconductor devices to be formed may be employed as alignment marks. Since an AFM is preferably employed, any feature on a chip may be used to align a next layer or mask. By using pattern recognition software, any existing, unique, array/support feature may be employed as the AFM Ultra-fine alignment mark.

In block 102, the area of the alignment mark is located. This may be performed by employing coarse optical alignment methods of the prior art. For example, an optical microscope or a pattern recognition algorithm may be employed to locate the alignment marks of the wafer. AFM scanning may also be employed to find the alignment marks. However, optical pre-alignment saves time over AFM scanning.

Current wafer alignment techniques employ optical pre-alignment with optical fine alignment. Optical methods may be employed to put the AFM system in close proximity to the acoustic alignment mark, hence reducing the amount of AFM scan time required and maximizing throughout. Current fine alignment optical marks are about 150 microns in size. An acoustic mark could be made 1/10^{th} or even 1/100^{th} the size and be placed anywhere in the chip. This would have the added benefit of reducing the necessary optical Kerf size and increase die/wafer productivity by reducing the alignment mark area thus increasing layout efficiency reserving more substrate areas for active devices.

Since the alignment marks are to include a material with different elastic properties as compared to the wafer, any feature may be employed for the alignment mark. By using pattern recognition software, the alignment mark of feature is identified among the many other features and components.

In block 104, energy is provided to cause stress fields in the area of the alignment marks. The energy may include ultrasonic energy. The energy is preferably focused on the wafer surface in the area of the alignment mark. Alternately, a vibrating cantilevered AFM tip may be employed to provide vibrational energy.

In block 106, when the stress field is applied, an AFM tip is employed to scan across a surface of the wafer. As the AFM tip is scanned elastic properties are measured and the boundaries of the alignment marks are determined.

In block 108, the results from block 106 are employed to align a subsequent exposure mask, etch mask or other tool to the wafer. Alignment algorithms or tools known in the art may be employed to perform the alignment. However, in accordance with the present invention, atomic scale alignment resolution is provided. For example, the alignment resolution may be about 10 to about 20 nm or better depending on the tip radius of the AFM tip. Also, thin film interference effects of optical systems are eliminated for fine alignment. For example, contrast problems, poor images and other optical effects are no longer at issue in the alignment process.

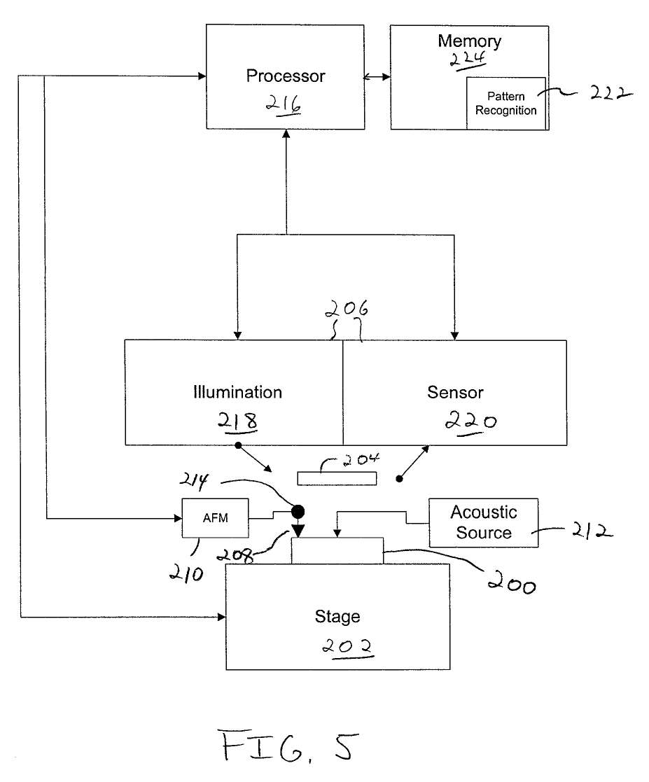

Referring to FIG. 5, an illustrative system for alignment mark detection and alignment of masks/tools with respect to a semiconductor wafer is shown in accordance with the present invention. A semiconductor wafer 200 is provided on a stage 202. Stage 202 provides rotation and translation of wafer 200 to align wafer 200 to pattern or mask 204. An optical system 206 is included to provide coarse alignment (e.g., pre-alignment) of an AFM tip 208 of an AFM 210. An acoustic source 212 may be provided or an oscillator or acoustic transmitter 214 may be employed with tip 208 preferably if tip 208 is a cantilevered tip.

Optical system 206 includes an illumination source 218, preferably a broadband illumination source, which irradiates wafer 200 with light. Optical system 206 includes a light sensor 220, which receives light from illumination source 218 to perform measurements for coarse alignment/AFM tip placement. Sensor 220 may be included in a peripheral device, such as a camera, for example, a CCD camera, which provides visual images.

One or more processors 216 may be employed to control stage 202, microscope 210 and optical system 206. Coarse alignment may be performed by pattern recognition software 222 stored in memory 224 and optical system 206. Images taken by optical system 206 are pattern recognized to determine the areas where alignment marks or features are located or AFM scanning may be employed for coarse and fine alignment. Coarse alignment may also be performed by known optical techniques. Memory 224 may include a program storage device readable by machine, tangibly embodying a program of instructions executable by the machine to perform method steps for deciphering the features or marks of a wafer and aligning a mask or tool to the wafer in accordance with electrical signals generated by the AFM.

Wafer 200 is scanned by AFM tip 208 in the presence of a stress field, preferably provided by acoustic energy or a vibrating AFM tip. Tip 208 is moved relative to stage 202 until alignment marks or features are deciphered on wafer 200. Signal data from AFM scanning is processed and or recorded in memory 224 to record the location of alignment marks. Signal data is processed and analyzed by known algorithms in processor 216. After an identification of alignment marks (either by optical or acoustic methods), a lithographic tool such as a scanner or stepper, will align a mask to a wafer to be “exposed” in the lithographic process. Mask 204 and alignment marks are then aligned, and lithographic exposure etc. is performed as is known in the art.

Having described preferred embodiments for ultra-fine alignment system and method using acoustic-AFM interaction (which are intended to be illustrative and not limiting), it is noted that modifications and variations can be made by persons skilled in the art in light of the above teachings. It is therefore to be understood that changes may be made in the particular embodiments of the invention disclosed which are within the scope and spirit of the invention as outlined by the appended claims. Having thus described the invention with the details and particularity required by the patent laws, what is claimed and desired protected by Letters Patent is set forth in the appended claims.

What is claimed is:

1. A method for deciphering an alignment feature, comprising the steps of:
providing a feature on a semiconductor wafer having an elasticity that is different from material surrounding the feature;
applying stress to the wafer; and
scanning the feature with an atomic force microscope to determine a position of the feature based on the elasticity difference between the feature and the material surrounding the feature.

2. The method as recited in claim 1, wherein the step of applying stress to the wafer includes the step of applying acoustic energy to the wafer.

3. The method as recited in claim 1, wherein the acoustic energy includes ultrasonic energy.

4. The method as recited in claim 1, wherein the atomic force microscope includes a cantilever tip and the step of applying stress to the wafer includes vibrating the cantilever tip.

5. The method as recited in claim 1, further comprising the step of determining a location of the feature by employing an optical method.

6. The method as recited in claim 5, wherein the optical method includes employing a pattern recognition method.

7. The method as recited in claim 1, further comprising the step of aligning a bullet mark on a mask to the feature.

8. The method as recited in claim 7, wherein the step of aligning provides an alignment resolution of less than 20 nm.

9. A system for aligning a pattern to a semiconductor wafer, comprising:
a feature formed on the wafer, the feature including an elasticity that is different from material surrounding the feature;
an acoustic source which directs an acoustic beam on the surface of the wafer to apply stress to the wafer; and
an atomic force microscope having a tip, the tip for scanning the feature to determine a position of the feature based on an elasticity difference detected between the feature and the material surrounding the feature.

10. The system as recited in claim 9, wherein the acoustic source includes an ultrasonic energy source.

11. The system as recited in claim 9, further comprising an optical system for determining a location of the feature.

12. The system as recited in claim 11, wherein the optical system includes a pattern recognition program to decipher an area where the feature is located.

13. The system as recited in claim 9, wherein the feature includes a portion of a functional component of a semiconductor device.

14. The system as recited in claim 9, further comprising a stage for aligning a mask with the feature on the wafer in accordance with information collected by the atomic force microscope.

15. The system as recited in claim 9, wherein the system provides an alignment resolution of less than 20 nm.

16. A system for aligning a pattern to a semiconductor wafer, comprising:
a feature formed on the wafer, the feature including an elasticity that is different from material surrounding the feature;
an atomic force microscope having a cantilevered tip; and
an acoustic transmitter coupled to the cantilevered tip to apply acoustical energy to the wafer by vibrating the cantilever tip such that the cantilevered tip scans the feature to determine a position of the feature based on the elasticity difference between the feature and the material surrounding the feature.

17. The system as recited in claim 16, further comprising an optical system for determining a location of the feature.

18. The system as recited in claim 17, wherein the optical system includes a pattern recognition program to decipher an area where the feature is located.

19. The system as recited in claim 16, wherein the feature includes a portion of a functional component of a semiconductor device.

20. The system as recited in claim 16, further comprising a stage for aligning a mask with the feature on the wafer in accordance with information collected by the atomic force microscope.

21. The system as recited in claim 16, wherein the system provides an alignment resolution of less than 20 nm.
